(19) United States
(12) Patent Application Publication
(10) Pub. No.: US 2026/0271690 A1
(43) Pub. Date: Sep. 10, 2026

(54) PULL-BACK SELECTIVE ETCHING PROCESSES

(71) Applicant: Applied Materials, Inc., Santa Clara, CA (US)

(72) Inventors: Wenting Hou, San Jose, CA (US); Rongjun Wang, Dublin, CA (US); Chih-Hsun Hsu, San Jose, CA (US); Jianxin Lei, Saratoga, CA (US)

(73) Assignee: Applied Materials, Inc., Santa C lara, CA (US)

(21) Appl. No.: 19/069,824

(22) Filed: Mar. 4, 2025

(51) Int. Cl. H01L 21/768; H01L 21/033; H01L 21/3205; H01L 21/3213

(52) U.S. Cl. CPC H10W 20/056; H10P 14/412; H10P 50/267; H10P 50/71; H10P 76/405; H10P 76/4085; H10W 20/067

(57) ABSTRACT

Pull-back selective etching processes for bottom-up selective metal gapfill are described. The processes include depositing a metallic layer on a substrate including a top surface and at least feature having sidewalls and a bottom; depositing a mask layer directly on the metallic layer; exposing the substrate to a first plasma to remove a portion of the mask layer; exposing the substrate to a second plasma to remove a portion of the metallic layer; exposing the substrate to a third plasma to remove any remaining portion of the mask layer; and depositing a conductive material in bottom-up fashion to fill the at least one feature.

### TECHNICAL FIELD

Embodiments of the disclosure generally relate to the manufacture of semiconductor devices. More particularly, embodiments of the disclosure are directed to pull-back selective etching processes for subsequent bottom-up selective metal gapfill.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Generally, front-end of line (FEOL) refers to the first portion of integrated circuit fabrication, including transistor fabrication, middle-of-line (MOL) connects the transistor and interconnect parts of a chip using a series of contact structures, and back-end of line (BEOL) refers to a series of process steps after transistor fabrication through completion of a wafer.

For bottom-up selective metal gapfill processes, selectively forming a metal layer on the bottom of the structure without any of the metal layer on the sidewall/field is critical. Physical vapor deposition (PVD) of metal typically has thicker field deposition than bottom with limited sidewall deposition, while chemical vapor deposition (CVD) of metal typically has a conformal profile with substantially similar thickness on each of the field, sidewall, and bottom. It remails a challenge to achieve the desired profile with deposition-only processes. As a result, a complicated and expensive pull-back process has been employed. Typically, this pull-back process includes a wet etch process or a dry etch process, both of which are facing challenges in features having small critical dimensions (CD) and decreasing technology nodes. In some pull-back processes, a capping layer with spin-on-carbon (SOC) is typically used to fill the trench, followed by SOC recess, metal etch, then SOC ashing.

Accordingly, there is a need for improved pull-back selective etching processes for subsequent bottom-up selective metal gapfill.

### SUMMARY

One or more embodiments of the disclosure are directed to a method comprising: depositing a metallic layer on a substrate including a top surface and at least one feature having sidewalls and a bottom; depositing a mask layer directly on the metallic layer; exposing the substrate to a first plasma to remove a portion of the mask layer; exposing the substrate to a second plasma to remove a portion of the metallic layer; and exposing the substrate to a third plasma to remove any remaining portion of the mask layer.

Additional embodiments of the disclosure are directed to a method comprising: depositing a metallic layer on a substrate including a top surface and at least one feature having sidewalls and a bottom; depositing a mask layer by atomic layer deposition (ALD) directly on the metallic layer; exposing the substrate to a first plasma composed of one or more of: chlorine (Cl₂), a mixture of chlorine (Cl₂) and a hydrocarbon, a mixture of chlorine (Cl₂) and nitrogen (N₂), a mixture of chlorine (Cl₂) and one or more inert gases, or a mixture of chlorine (Cl₂) and hydrogen (H₂) to remove a portion of the mask layer; exposing the substrate to a second plasma composed of a mixture of chlorine (Cl₂) and oxygen (O₂) to remove a portion of the metallic layer; exposing the substrate to a third plasma composed of one or more of: chlorine (Cl₂), a mixture of chlorine (Cl₂) and a hydrocarbon, a mixture of chlorine (Cl₂) and nitrogen (N₂), a mixture of chlorine (Cl₂) and one or more inert gases, or a mixture of chlorine (Cl₂) and hydrogen (H₂) to remove any remaining portion of the mask layer; and depositing a conductive material in bottom-up fashion to fill the at least one feature.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method in accordance with one or more embodiments of the disclosure;

FIG. 2A illustrates a schematic cross-sectional view of a substrate including a top surface and a feature having sidewalls and a bottom in accordance with one or more embodiments of the disclosure;

FIG. 2B illustrates a cross-sectional schematic view of deposition of a metallic layer on the top surface of the substrate, on the sidewalls, and on the bottom in accordance with one or more embodiments of the disclosure;

FIG. 2C illustrates a cross-sectional schematic view of deposition of a mask layer directly on the metallic layer in accordance with one or more embodiments of the disclosure;

FIG. 2D illustrates a cross-sectional schematic view of the substrate after exposure to a first plasma to remove a portion of the mask layer in accordance with one or more embodiments of the disclosure;

FIG. 2E illustrates a cross-sectional schematic view of the substrate after exposure to a second plasma to remove a portion of the metallic layer in accordance with one or more embodiments of the disclosure;

FIG. 2F illustrates a cross-sectional schematic view of the substrate after exposure to a third plasma to remove any remaining portion of the mask layer in accordance with one or more embodiments of the disclosure; and

FIG. 3 illustrates a cross-sectional schematic view of the substrate after performing a bottom-up selective gapfill process to fill the feature in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the structure (e.g., substrate) in use or operation in addition to the orientation depicted in the Figures. For example, if the substrate in the Figures is turned over, elements described as “below” or “beneath” other elements would then be oriented “above” the other elements. Thus, the exemplary term “below” may encompass both an orientation of above and below. The substrate may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to “depositing on” or “forming on” a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. In some embodiments, the substrate comprises one or more of doped or undoped crystalline silicon (Si), doped or undoped crystalline silicon germanium (SiGe), doped or undoped amorphous silicon (Si), or doped or undoped amorphous silicon germanium (SiGe).

Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

Sputtering is a physical vapor deposition (PVD) process in which high-energy ions impact and erode a solid target and deposit the target material on the surface of a substrate, such as a semiconductor substrate. In semiconductor fabrication, the sputtering process is usually accomplished within a semiconductor fabrication chamber also known as a PVD processing chamber or a sputtering chamber. Sputtering has long been used for the deposition of metals and related materials in the fabrication of semiconductor integrated circuits.

Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the semiconductor substrate. In the sputtering processes, the sputtering target is bombarded by energetic ions, such as a plasma, causing material to be knocked off the target and deposited as a film on the semiconductor substrate.

A typical semiconductor fabrication chamber has a target assembly including disc-shaped target of solid metal or other material supported by a backing plate that holds the target. To promote uniform deposition, the PVD chamber may have an annular concentric metallic ring, which is often called a shield, circumferentially surrounding the disc-shaped target.

Plasma sputtering may be accomplished using either DC sputtering or RF sputtering. Plasma sputtering typically includes a magnetron positioned at the back of a sputtering target including two magnets of opposing poles magnetically coupled at their back through a magnetic yoke to project a magnetic field into the processing space to increase the density of the plasma and enhance the sputtering rate from a front face of the target.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, “substantially simultaneously” means that most of the duration of the first reactive species exposure overlaps with the second reactive species exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the reaction chamber for a time duration in a range of from 0.1 seconds to 30 seconds, for example, before exposing the substrate to the second reactive species.

“Cyclical deposition” or “atomic layer deposition” (ALD) refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired layer or layer thickness is formed on the substrate surface. In either scenario, the ALD process of pulsing compound A, purge gas, compound B and purge gas is a cycle. A cycle can start with either compound A or compound B and continue the respective order of the cycle until achieving a layer with the predetermined thickness.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Generally, front-end of line (FEOL) refers to the first portion of integrated circuit fabrication, including transistor fabrication, middle-of-line (MOL) connects the transistor and interconnect parts of a chip using a series of contact structures, and back-end of line (BEOL) refers to a series of process steps after transistor fabrication through completion of a wafer. The methods described herein can advantageously be used in MOL and/or BEOL processes.

The methods described herein can advantageously be used in a backside power delivery network (BSPDN). As used herein, “backside power delivery” refers to the technique of routing power supply lines on the backside of a semiconductor chip or integrated circuit (IC). Without intending to be bound by any particular theory, it is thought that backside power delivery increases logic density and improves power and performance.

Embodiments of the disclosure are directed to pull-back selective etching processes for subsequent bottom-up selective metal gapfill in the fabrication of semiconductor devices, including, but not limited to, logic devices and/or memory devices.

For bottom-up selective metal gapfill processes, selectively forming a metal layer on the bottom of the structure without any of the metal layer on the sidewall/field is critical. Physical vapor deposition (PVD) of metal typically has thicker field deposition than bottom with limited sidewall deposition, while chemical vapor deposition (CVD) of metal typically has a conformal profile with substantially similar thickness on each of the field, sidewall, and bottom. It remails a challenge to achieve the desired profile with deposition-only processes. As a result, a complicated and expensive pull-back process has been employed. Typically, this pull-back process includes a wet etch process or a dry etch process, both of which are facing challenges in features having small critical dimensions (CD) and decreasing technology nodes. In some pull-back processes, a capping layer with spin-on-carbon (SOC) is typically used to fill the trench, followed by SOC recess, metal etch, then SOC ashing.

The pull-back selective etching processes of the present disclosure include depositing a metallic layer on a substrate including a top surface (i.e., field) and at least one feature having sidewalls and a bottom; depositing a mask layer directly on the metallic layer; exposing the substrate to a first plasma to remove a portion of the mask layer; exposing the substrate to a second plasma to remove a portion of the metallic layer; and exposing the substrate to a third plasma to remove any remaining portion of the mask layer. In one or more embodiments, there is a non-volatile residue mixture of metal from the metallic layer, and chlorine and oxygen from the second plasma. In one or more embodiments, exposing the substrate to the third plasma is configured to remove the non-volatile residue mixture. The use of the mask layer in the pull-back selective etching processes described herein advantageously improves the etch gradient between the field and the bottom. After the pull-back selective etching process, a bottom-up selective metal gapfill process is performed. In one or more embodiments, a bottom-up selective metal gapfill process includes depositing a conductive material on the metallic layer on the bottom to fill the at least one feature.

The pull-back selective etching processes and subsequently performed bottom-up selective metal gapfill processes of the present disclosure can advantageously be used in features having small critical dimensions (CD) and decreasing technology nodes. The pull-back selective etching processes of the present disclosure advantageously provide simplified integration steps. The pull-back selective etching processes of the present disclosure advantageously provide improved process control. The pull-back selective etching processes of the present disclosure advantageously provide less dielectric damage compared to current pull-back processes, e.g., using a capping layer with spin-on-carbon (SOC) to fill the trench, followed by SOC recess, metal etch, then SOC ashing.

The pull-back selective etching processes of the present disclosure include a plurality of different chemistries and advantageously improve etching selectivity between the mask layer, metallic layer, and dielectric material. The pull-back selective etching processes of the present disclosure advantageously provide selective metal deposition on the bottom and substantially no metal deposition on the sidewall and/or field.

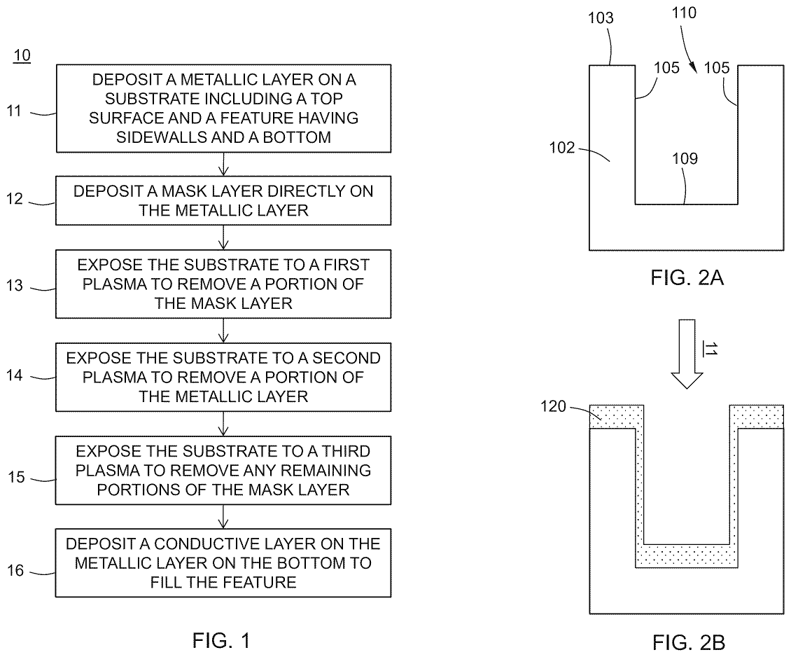

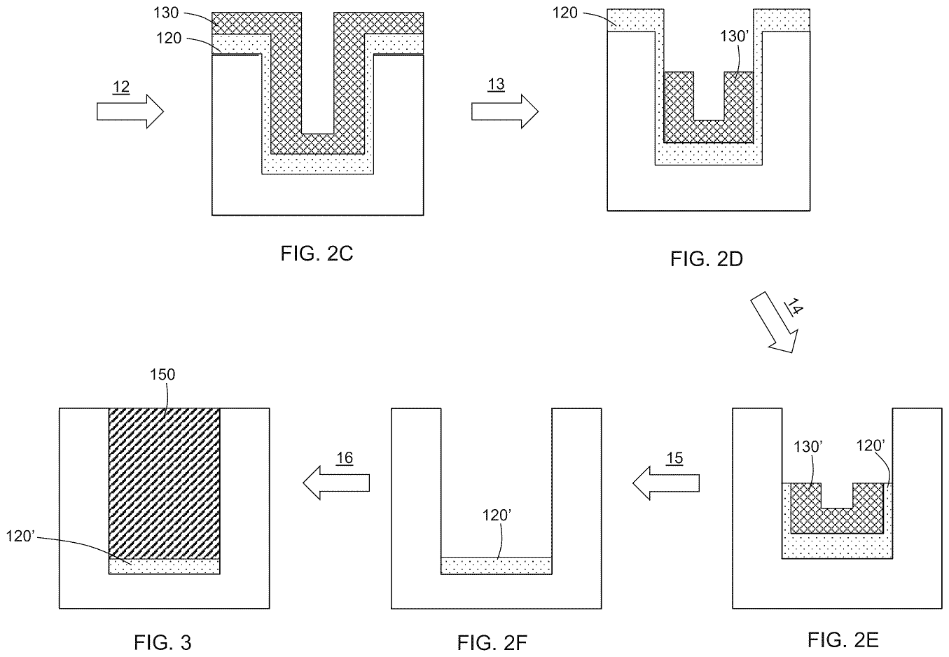

The pull-back selective etching processes of the present disclosure are described with reference to FIG. 1 and FIGS. 2A-2F. After the pull-back selective etching process, a bottom-up selective metal gapfill process is performed, as illustrated in FIG. 3.

FIG. 1 illustrates a process flow diagram of a method 10. FIGS. 2B-2F and 3 illustrate schematic cross-sectional views of stages of processing a substrate 102 in accordance with the method 10. In one or more embodiments, the method 10 optionally includes pre-cleaning the substrate 102. In one or more embodiments, keeping the pre-cleaning process under vacuum ensures that no oxide is introduced/formed on the substrate 102 during the method 10. In one or more embodiments, pre-cleaning the substrate 102 is configured to remove native oxides from one or more surfaces of the substrate 102.

The pre-cleaning process can be any suitable process. In some embodiments, the pre-cleaning process is configured to remove metal oxide from the one or more surfaces and maintains the integrity of the dielectric surface. As used herein, the term “substrate 102” can be used to refer to a substrate and/or a pre-cleaned substrate, unless the context clearly indicates otherwise.

The method 10 can be performed at any suitable processing conditions, and the processing conditions may vary based upon the application in which the substrate 102 is used, unless otherwise specifically indicated.

The method 10 includes, at operation 11, depositing a metallic layer 120 on the substrate 102. The substrate 102 includes a top surface (referred to herein as “field 103”) and at least one feature 110. The at least one feature 110 has sidewalls 105 and a bottom 109.

The sidewalls 105 and the bottom 109 may comprise any suitable material, respectively. In one or more embodiments, the sidewalls 105 comprise a dielectric material. The dielectric material can include any suitable dielectric material. In one or more embodiments, the sidewalls 105 comprise a low-κ dielectric material. In one or more embodiments, the sidewalls 105 comprise silicon oxide. In one or more embodiments, the bottom 109 comprises a metallic material. The metallic material can include any suitable metallic material. In one or more embodiments, the bottom 109 comprises one or more of ruthenium (Ru), copper (Cu), cobalt (cobalt), molybdenum (Mo), tantalum (Ta), or tungsten (W). In one or more embodiments, the bottom 109 comprises one or more of titanium silicide (TiSi), titanium silicon nitride (TiSiN), titanium nitride (TiN), or molybdenum silicide (MoSi).

The Figures show a substrate 102 having a single feature for illustrative purposes; however, those skilled in the art will understand that there can be more than one feature.

As used herein, the term “feature” means any intentional surface irregularity. Suitable examples of features include but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 1:1, 2:1, 5:1, 10:1, 15:1, 20:1, 25:1, 30:1, 35:1, 40:1, 50:1, 100:1, or 500:1.

In some embodiments, the at least one feature 110 defines a cylindrical via that, when filled with metal, transfers current between layers, and lines that transfer current within the same device layer. In one or more embodiments, the at least one feature 110 is a trench having an aspect ratio in a range of from 1:1 to 500:1.

The metallic layer 120 can be deposited on or directly on the substrate 102 by any suitable deposition technique, including, but not limited to physical vapor deposition (PVD), chemical vapor deposition (CVD), or atomic layer deposition (ALD). In some embodiments, the metallic layer 120 is deposited by physical vapor deposition (PVD). In some embodiments, the metallic layer 120 is deposited by chemical vapor deposition (CVD). In some embodiments, the metallic layer 120 is deposited by atomic layer deposition (ALD). The metallic layer 120 can have any suitable thickness.

The metallic layer 120 can include any metal material. In some embodiments, the metallic layer 120 comprises, consists essentially of, or consists of a transition metal. In some embodiments, the metallic layer 120 comprises, consists essentially of, or consists of molybdenum (Mo). In some embodiments, the metallic layer 120 comprises, consists essentially of, or consists of tungsten (W).

The method 10 includes, at operation 12, depositing a mask layer 130 on or directly on the metallic layer 120. The mask layer 130 can be deposited by any suitable deposition technique, including, but not limited to physical vapor deposition (PVD), chemical vapor deposition (CVD), or atomic layer deposition (ALD). In some embodiments, the mask layer 130 is deposited by atomic layer deposition (ALD). In some embodiments, the mask layer 130 is conformally deposited by atomic layer deposition (ALD). As used herein, a layer which is “conformal” (inclusive of “conformally deposited”) refers to a layer where the thickness is about the same throughout (e.g., on the top, middle and bottom of sidewalls 105 and on the bottom 109). A layer which is substantially conformal varies in thickness by less than or equal to about 5%, 2%, 1% or 0.5%. The mask layer 130 can have any suitable thickness.

The mask layer 130 can include any suitable material that has greater etch selectivity relative to the metallic layer 120. Stated differently, where the mask layer 130 has greater etch selectivity relative to the metallic layer 120, this means that the mask layer 130 is etched (i.e., removed) at a slower rate than the metallic layer 120. Where the mask layer 130 has greater etch selectivity relative to the metallic layer 120, the metallic layer 120 has a greater etch rate than the mask layer 130.

In one or more embodiments, the mask layer 130 comprises, consists essentially of, or consists of a metal nitride. In one or more embodiments, the mask layer 130 comprises, consists essentially of, or consists of titanium nitride (TiN).

The method 10 includes, at operation 13, exposing the substrate 102 to a first plasma to remove a portion of the mask layer 130. In one or more embodiments, exposing the substrate 102 to the first plasma to remove a portion of the mask layer 130 is configured to form an etched mask layer 130′. In one or more embodiments, exposing the substrate 102 to the first plasma is configured to remove the portion of the mask layer 130 formed on the metallic layer 120 on the field 103 and a portion of the sidewalls 105. In one or more embodiments, after exposing the substrate 102 to the first plasma, the remaining portion of the mask layer 130, i.e., the etched mask layer 130′ is present on the metallic layer 120 on the sidewalls 105 and on the metallic layer 120 on the bottom 109. In one or more embodiments, exposing the substrate 102 to the first plasma is configured to remove none or substantially none of the metallic layer 120.

The first plasma is composed of one or more of: chlorine (Cl₂), a mixture of chlorine (Cl₂) and a hydrocarbon, a mixture of chlorine (Cl₂) and nitrogen (N₂), a mixture of chlorine (Cl₂) and one or more inert gases, or a mixture of chlorine (Cl₂) and hydrogen (H₂). In embodiments where the first plasma is composed of a mixture, the mixture can include any suitable ratio of the components in the mixture.

The hydrocarbon can include, without limitation, any compound comprising hydrogen (H) atoms and carbon (C) atoms. The hydrocarbon according to one or more embodiments may include substituted or unsubstituted linear hydrocarbon chains, substituted or unsubstituted branched hydrocarbon chains, or substituted or unsubstituted aryl hydrocarbon chains. In one or more embodiments, the hydrocarbon comprises a saturated hydrocarbon. As used herein, a “saturated hydrocarbon” refers to a compound with only single bonds. In one or more embodiments, the hydrocarbon comprises a saturated hydrocarbon having in a range of from 1 to 25 carbon (C) atoms. In one or more embodiments, the saturated hydrocarbon is a substituted or unsubstituted linear hydrocarbon chain, substituted or unsubstituted branched hydrocarbon chain, or substituted or unsubstituted aryl hydrocarbon chain having in a range of from 1 to 25 carbon (C) atoms.

In one or more embodiments, the hydrocarbon comprises an unsaturated hydrocarbon. The unsaturated hydrocarbon can include any compound that includes an unsaturated bond (e.g., a double bond and/or a triple bond), hydrogen (H) atoms, and carbon (C) atoms.

In one or more embodiments, the “one or more inert gases” described herein includes helium (He), neon (Ne), argon (Ar), krypton (Kr), and xenon (Xe).

In some embodiments, the first plasma comprises, consists essentially of, or consists of chlorine (Cl₂). In some embodiments, the first plasma comprises, consists essentially of, or consists of a mixture of chlorine (Cl₂) and methane (CH₄). In some embodiments, the first plasma comprises, consists essentially of, or consists of a mixture of chlorine (Cl₂) and nitrogen (N₂). In some embodiments, the first plasma comprises, consists essentially of, or consists of a mixture of chlorine (Cl₂) and the one or more inert gases. In some embodiments, the first plasma comprises, consists essentially of, or consists of a mixture of chlorine (Cl₂) and hydrogen (H₂).

The substrate 102 can be exposed to the first plasma at any suitable processing conditions, and the processing conditions may vary based upon the application in which the substrate 102 is used, unless otherwise specifically indicated.

The substrate 102 can be exposed to the first plasma at any suitable temperature. In one or more embodiments, the substrate 102 is exposed to the first plasma at a temperature in a range of from 0° C. to 80° C. In some embodiments, the substrate 102 is exposed to the first plasma at a temperature in a range of from 0° C. to 75° C., in a range of from 0° C. to 70° C., in a range of from 0° C. to 65° C., in a range of from 0° C. to 60° C., in a range of from 0° C. to 50° C., in a range of from 0° C. to 40° C., in a range of from 0° C. to 30° C., in a range of from 0° C. to 20° C., or in a range of from 0° C. to 10° C.

The substrate 102 can be exposed to the first plasma for any suitable duration of time. In one or more embodiments, the substrate 102 is exposed to the first plasma for a time period in a range of from 1 second to 120 seconds. In one or more embodiments, the substrate 102 is exposed to the first plasma for a time period in a range of from 10 seconds to 120 seconds, in a range of from 20 seconds to 120 seconds, in a range of from 50 seconds to 120 seconds, or in a range of from 70 seconds to 120 seconds. In one or more embodiments, the substrate 102 is exposed to the first plasma for a time period of 25 seconds. In one or more embodiments, the substrate 102 is exposed to the first plasma for a time period of 50 seconds. In one or more embodiments, the substrate 102 is exposed to the first plasma for a time period of 70 seconds.

The method 10 includes, at operation 14, exposing the substrate 102 to a second plasma to remove a portion of the metallic layer 120. In one or more embodiments, exposing the substrate 102 to the second plasma to remove a portion of the metallic layer 120 is configured to form an etched metallic layer 120′. In one or more embodiments, exposing the substrate 102 to the second plasma is configured to remove the portion of the metallic layer 120 on the field 103 and a portion of the sidewalls 105. In one or more embodiments, after exposing the substrate 102 to the second plasma, the remaining portion of the metallic layer 120, i.e., the etched metallic layer 120′ is present on the bottom 109. In one or more embodiments, after exposing the substrate 102 to the second plasma, the remaining portion of the metallic layer 120, i.e., the etched metallic layer 120′ is present on the bottom 109 only and not on the sidewalls 105.

The second plasma comprises, consists essentially of, or consists of a mixture of chlorine (Cl₂) and oxygen (O₂). The second plasma comprising, consisting essentially of, or consisting of the mixture of chlorine (Cl₂) and oxygen (O₂) has greater etch selectivity between the metallic layer 120 and the etched mask layer 130′. In one or more embodiments, the second plasma comprising, consisting essentially of, or consisting of the mixture of chlorine (Cl₂) and oxygen (O₂) has greater etch selectivity between the metallic layer 120 (e.g., tungsten (W)) and the etched mask layer 130′ (e.g., titanium nitride (TiN)). In one or more embodiments, the second plasma comprising, consisting essentially of, or consisting of the mixture of chlorine (Cl₂) and oxygen (O₂) etches the metallic layer 120 (e.g., tungsten (W)) at a greater etch rate than the etched mask layer 130′ (e.g., titanium nitride (TiN)). In one or more embodiments, the second plasma comprising, consisting essentially of, or consisting of the mixture of chlorine (Cl₂) and oxygen (O₂) etches the metallic layer 120 (e.g., tungsten (W)) at a greater etch rate than the dielectric material of the sidewalls 105. In one or more embodiments, the second plasma comprising, consisting essentially of, or consisting of the mixture of chlorine (Cl₂) and oxygen (O₂) etches the metallic layer 120 (e.g., tungsten (W)) at a greater etch rate than each of the etched mask layer 130′ (e.g., titanium nitride (TiN)) and the dielectric material of the sidewalls 105.

In some embodiments, the mixture of chlorine (Cl₂) and oxygen (O₂) has a Cl₂:O₂ ratio in a range of from 20:1 to 1:1. In some embodiments, the mixture of chlorine (Cl₂) and oxygen (O₂) has a Cl₂:O₂ ratio in a range of from 10:1 to 5:1.

The substrate 102 can be exposed to the second plasma at any suitable processing conditions, and the processing conditions may vary based upon the application in which the substrate 102 is used, unless otherwise specifically indicated.

The substrate 102 can be exposed to the second plasma at any suitable temperature. In one or more embodiments, the substrate 102 is exposed to the second plasma at a temperature in a range of from 30° C. to 200° C. In some embodiments, the substrate 102 is exposed to the second plasma at a temperature in a range of from 50° C. to 200° C., in a range of from 60° C. to 200° C., in a range of from 60° C. to 150° C., or in a range of from 60° C. to 120° C. It has been advantageously found that exposing the substrate 102 to the second plasma at a temperature in a range of from 30° C. to 200° C. improves etch on the field 103 without damage to the bottom 109 (e.g., the bottom 109 including the etched mask layer 130′ present thereon). Without intending to be bound by theory, it is also thought that exposing the substrate 102 to the second plasma at a temperature in a range of from 30° C. to 200° C. advantageously minimizes the amount of by-products and/or residue in or on the substrate 102.

The substrate 102 can be exposed to the second plasma for any suitable duration of time. In one or more embodiments, the substrate 102 is exposed to the second plasma for a time period in a range of from 1 second to 240 seconds. In one or more embodiments, the substrate 102 is exposed to the second plasma for the time period in the range of from 1 second to 240 seconds, and the time period varies depending on the structure of the substrate 102 and the thickness of the layers thereon.

In one or more embodiments, after exposing the substrate 102 to the second plasma at operation 14, there is a non-volatile residue mixture of metal from the metallic layer 120, and chlorine and oxygen from the second plasma comprising, consisting essentially of, or consisting of the mixture of chlorine (Cl₂) and oxygen (O₂). The non-volatile residue mixture may be present on the field 103 and inside the at least one feature 110.

The method 10 includes, at operation 15, exposing the substrate 102 to a third plasma, and the third plasma is configured to remove any remaining portion of the mask layer 130 (the etched mask layer 130′). In one or more embodiments, exposing the substrate 102 to the third plasma at operation 15 is configured to remove the non-volatile residue mixture of metal from the metallic layer 120, and chlorine and oxygen from the second plasma comprising, consisting essentially of, or consisting of the mixture of chlorine (Cl₂) and oxygen (O₂). In one or more embodiments, exposing the substrate 102 to the third plasma at operation 15 is configured to entirely remove the non-volatile residue mixture of metal from the metallic layer 120, and chlorine and oxygen from the second plasma comprising, consisting essentially of, or consisting of the mixture of chlorine (Cl₂) and oxygen (O₂), including from the field 103 and/or inside the at least one feature 110. In one or more embodiments, the first plasma and the third plasma are the same. In one or more embodiments, the processing conditions used for each of the first plasma and the third plasma are the same.

It has been advantageously found that exposing the substrate 102 to the third plasma at operation 15 at a temperature in a range of from 0° C. to 80° C. provides greater etch selectivity between the etched mask layer 130′, the non-volatile residue mixture, and the etched metallic layer 120′ on the bottom 109. It has been advantageously found that exposing the substrate 102 to the third plasma at operation 15 at a temperature in a range of from 0° C. to 80° C. entirely removes the etched mask layer 130′ and the non-volatile residue mixture, and does not remove the etched metallic layer 120′ on the bottom 109.

The pull-back selective etching processes of the present disclosure advantageously provide selective metal deposition on the bottom and substantially no metal deposition on the sidewall and/or field. In one or more embodiments, after exposing the substrate 102 to the third plasma, the etched mask layer 130′ is entirely removed and the etched metallic layer 120′ is present on the bottom 109.

The plasmas described herein, e.g., the first plasma, the second plasma, and the third plasma, can be independently generated by any suitable plasma source. In some embodiments, one or more of the first plasma, the second plasma, or the third plasma, is generated by a remote plasma source (RPS), capacitively coupled plasma (CCP) source, inductively coupled plasma (ICP) source, or a microwave plasma source. In some embodiments, each of the first plasma, the second plasma, and the third plasma, are independently generated by the same remote plasma source (RPS), capacitively coupled plasma (CCP) source, inductively coupled plasma (ICP) source, or microwave plasma source.

Referring to FIG. 3, the method 10 includes, at operation 16, depositing a conductive material 150 on the metallic layer 120 (i.e., the etched metallic layer 120′) on the bottom 109 to fill the at least one feature 110. In one or more embodiments, the conductive material 150 is deposited on the etched metallic layer 120′ in bottom-up fashion.

The conductive material 150 can be deposited by any suitable deposition technique. In one or more embodiments, the conductive material 150 is deposited by physical vapor deposition (PVD).

The conductive material 150 may include any suitable conductive material. In one or more embodiments, the conductive material 150 comprises one or more of copper (Cu), cobalt (Co), ruthenium (Ru), tungsten (W), or molybdenum (Mo). In one or more embodiments, the conductive material 150 is substantially free of seams and/or voids or free of seams and/or voids. As used in this regard, “substantially free” means that less than about 5%, including less than about 4%, less than about 3%, less than about 2%, less than about 1%, less than about 0.5%, and less than about 0.1% of the total composition of the conductive material 150 on an atomic basis, comprises seams and/or voids. Advantageously, in one or more embodiments, the conductive material 150 is free of seams and/or voids.

In one or more embodiments, the method 10 comprises, consists essentially of, or consists of operation 11, operation 12, operation 13, operation 14, operation 15, and operation 16. One or more of the operations of the method 10 can be repeated any suitable number of times depending on the specific application.

In specific embodiments, the method 10 comprises, consists essentially of, or consists of: depositing a tungsten (W) layer on a substrate including a top surface and at least one feature having sidewalls and a bottom (operation 11); depositing a titanium nitride (TiN) layer by atomic layer deposition (ALD) directly on the tungsten (W) layer (operation 12); exposing the substrate to a first plasma composed of one or more of: chlorine (Cl₂), a mixture of chlorine (Cl₂) and a hydrocarbon, a mixture of chlorine (Cl₂) and nitrogen (N₂), a mixture of chlorine (Cl₂) and one or more inert gases, or a mixture of chlorine (Cl₂) and hydrogen (H₂) to remove a portion of the titanium nitride (TiN) layer (operation 13); exposing the substrate to a second plasma composed of a mixture of chlorine (Cl₂) and oxygen (O₂) to remove a portion of the tungsten (W) layer (operation 14); exposing the substrate to a third plasma composed of one or more of: chlorine (Cl₂), a mixture of chlorine (Cl₂) and a hydrocarbon, a mixture of chlorine (Cl₂) and nitrogen (N₂), a mixture of chlorine (Cl₂) and one or more inert gases, or a mixture of chlorine (Cl₂) and hydrogen (H₂) to remove any remaining portion of the titanium nitride (TiN) layer (operation 15); and depositing a conductive material in bottom-up fashion to fill the at least one feature (operation 16).

In specific embodiments, the method 10 comprises, consists essentially of, or consists of: depositing a molybdenum (Mo) layer on a substrate including a top surface and at least one feature having sidewalls and a bottom (operation 11); depositing a titanium nitride (TiN) layer by atomic layer deposition (ALD) directly on the molybdenum (Mo) layer (operation 12); exposing the substrate to a first plasma composed of one or more of: chlorine (Cl₂), a mixture of chlorine (Cl₂) and a hydrocarbon, a mixture of chlorine (Cl₂) and nitrogen (N₂), a mixture of chlorine (Cl₂) and one or more inert gases, or a mixture of chlorine (Cl₂) and hydrogen (H₂) to remove a portion of the titanium nitride (TiN) layer (operation 13); exposing the substrate to a second plasma composed of a mixture of chlorine (Cl₂) and oxygen (O₂) to remove a portion of the molybdenum (Mo) layer (operation 14); exposing the substrate to a third plasma composed of one or more of: chlorine (Cl₂), a mixture of chlorine (Cl₂) and a hydrocarbon, a mixture of chlorine (Cl₂) and nitrogen (N₂), a mixture of chlorine (Cl₂) and one or more inert gases, or a mixture of chlorine (Cl₂) and hydrogen (H₂) to remove any remaining portion of the titanium nitride (TiN) layer (operation 15); and depositing a conductive material in bottom-up fashion to fill the at least one feature (operation 16).

Accordingly, it will be appreciated by the skilled artisan that one or more additional operations needed to complete the processing of the substrate 102 are known to the skilled artisan and are within the scope of the disclosure without undue experimentation.

In one or more embodiments, the methods described herein comprise an optional post-processing operation. The optional post-processing operation can be, for example, a process to modify film properties.

In some embodiments, the optional post-processing operation comprises annealing the substrate. In some embodiments, the annealing process is performed at temperatures in the range of from 300° C. to 1000° C. The annealing environment of some embodiments comprises one or more of an inert gas or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the substrate is annealed for a predetermined time in the range of about 15 seconds to about 90 minutes, or in the range of about 1 minute to about 60 minutes. In some embodiments, annealing the substrate increases the density, decreases the resistivity and/or increases the purity of the layers.

In one or more embodiments, one or more of the operations of the methods described herein are performed in situ in an integrated processing system, without an intervening vacuum break. In one or more embodiments, each of the operations of the methods described are performed in situ, without an intervening vacuum break. In one or more embodiments, one or more of the operations of the methods described herein are performed ex situ, such that one or more of the processes are performed with an intervening vacuum break.

The methods described herein can be performed any suitable processing system. The particular arrangement of processing chambers and components in the processing system can be varied depending on the processing system and should not be taken as limiting the scope of the disclosure.

Processes may generally be stored in the memory of a system controller as a software routine that, when executed by the processor, causes the processing system to perform one or more of the operations of any of the methods described herein. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the processing system operation such that one or more of the operations of any of the methods described herein are performed.

One or more embodiments of the disclosure are directed to a non-transitory computer readable medium including instructions that, when executed by a controller of a processing system, causes the processing system to perform one or more of the operations of any of the methods described herein.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method comprising:
depositing a metallic layer on a substrate including a top surface and at least one feature having sidewalls and a bottom;
depositing a mask layer directly on the metallic layer;
exposing the substrate to a first plasma to remove a portion of the mask layer;
exposing the substrate to a second plasma to remove a portion of the metallic layer; and
exposing the substrate to a third plasma to remove any remaining portion of the mask layer.

2. The method of claim 1, wherein the metallic layer is deposited by physical vapor deposition (PVD), chemical vapor deposition (CVD), or atomic layer deposition (ALD).

3. The method of claim 2, wherein the metallic layer comprises tungsten (W).

4. The method of claim 1, wherein the mask layer is conformally deposited on the metallic layer by atomic layer deposition (ALD).

5. The method of claim 4, wherein the mask layer comprises titanium nitride (TiN).

6. The method of claim 1, wherein the first plasma is composed of one or more of: chlorine (Cl₂), a mixture of chlorine (Cl₂) and a hydrocarbon, a mixture of chlorine (Cl₂) and nitrogen (N₂), a mixture of chlorine (Cl₂) and one or more inert gases, or a mixture of chlorine (Cl₂) and hydrogen (H₂).

7. The method of claim 6, wherein the first plasma is composed of a mixture of chlorine (Cl₂) and methane (CH₄).

8. The method of claim 6, wherein the substrate is exposed to the first plasma at a temperature in a range of from 0° C. to 80° C.

9. The method of claim 6, wherein the substrate is exposed to the first plasma for a time period in a range of from 1 second to 120 seconds.

10. The method of claim 1, wherein the second plasma is composed of a mixture of chlorine (Cl₂) and oxygen (O₂).

11. The method of claim 10, wherein the mixture of chlorine (Cl₂) and oxygen (O₂) has a Cl₂:O₂ ratio in a range of from 20:1 to 1:1.

12. The method of claim 10, wherein the substrate is exposed to the second plasma at a temperature in a range of from 30° C. to 200° C.

13. The method of claim 1, wherein the third plasma is composed of one or more of: chlorine (Cl₂), a mixture of chlorine (Cl₂) and a hydrocarbon, a mixture of chlorine (Cl₂) and nitrogen (N₂), a mixture of chlorine (Cl₂) and one or more inert gases, or a mixture of chlorine (Cl₂) and hydrogen (H₂).

14. The method of claim 13, wherein the substrate is exposed to the third plasma at a temperature in a range of from 0° C. to 80° C.

15. The method of claim 1, further comprising depositing a conductive material in bottom-up fashion after remove the remaining portion of the mask layer to fill the at least one feature.

16. The method of claim 1, performed in situ in an integrated processing system.

17. A method comprising:
depositing a metallic layer on a substrate including a top surface and at least one feature having sidewalls and a bottom;
depositing a mask layer by atomic layer deposition (ALD) directly on the metallic layer;
exposing the substrate to a first plasma composed of one or more of: chlorine (Cl₂), a mixture of chlorine (Cl₂) and a hydrocarbon, a mixture of chlorine (Cl₂) and nitrogen (N₂), a mixture of chlorine (Cl₂) and one or more inert gases, or a mixture of chlorine (Cl₂) and hydrogen (H₂) to remove a portion of the mask layer;
exposing the substrate to a second plasma composed of a mixture of chlorine (Cl₂) and oxygen (O₂) to remove a portion of the metallic layer;
exposing the substrate to a third plasma composed of one or more of: chlorine (Cl₂), a mixture of chlorine (Cl₂) and a hydrocarbon, a mixture of chlorine (Cl₂) and nitrogen (N₂), a mixture of chlorine (Cl₂) and one or more inert gases, or a mixture of chlorine (Cl₂) and hydrogen (H₂) to remove any remaining portion of the mask layer; and
depositing a conductive material in bottom-up fashion to fill the at least one feature.

18. The method of claim 17, wherein the first plasma is composed of a mixture of chlorine (Cl₂) and methane (CH₄).

19. The method of claim 17, wherein the mixture of chlorine (Cl₂) and oxygen (O₂) has a Cl₂:O₂ ratio in a range of from 20:1 to 1:1.

20. The method of claim 17, wherein the substrate is independently exposed to the first plasma and the third plasma at a temperature in a range of from 0° C. to 80° C., and the substrate is exposed to the second plasma at a temperature in a range of from 50° C. to 200° C.
